(19) United States
(12) Patent Application Publication
(10) Pub. No.: US 2021/0288295 A1
(43) Pub. Date: Sep. 16, 2021

(54) PIXEL DEFINING LAYER, MANUFACTURING METHOD THEREFOR, DISPLAY SUBSTRATE, AND DISPLAY DEVICE

(71) Applicant: BOE TECHNOLOGY GROUP CO., LTD., Beijing (CN)

(72) Inventor: Yingying SONG, Beijing (CN)

(21) Appl. No.: 16/323,399

(22) PCT Filed: Apr. 12, 2018
(86) PCT No.: PCT/CN2018/082826

§ 371 Date: Feb. 5, 2019

(30) Foreign Application Priority Data
May 11, 2017 (CN) 201710330762.1

(51) Int. Cl. H01L 51/56; H01L 27/32

(52) U.S. Cl. CPC H01L 51/56; H01L 27/3283; H01L 27/3246

(57) ABSTRACT

Provided are a pixel defining layer, a manufacturing method therefor, a display substrate, and a display device. The method includes: providing a base substrate; forming a lyophilic layer on the base substrate, the lyophilic layer including a top surface and a lateral surface; forming a lyophobic layer covering at least the top surface of the lyophilic layer and a surface covering layer covering at least a part of the lateral surface of the lyophilic layer, the part of the lateral surface being the part of the lateral surface in proximity to the base substrate; and removing the surface covering layer, thus exposing at least the part of the lateral surface in proximity to the base substrate and forming a pixel defining layer. The manufacturing method reduces the extent to which a solution climbs on the lateral surface, thus reducing the impact on film uniformity in a pixel region.

### CROSS-REFERENCE TO RELATED APPLICATIONS

The present application claims priority to the Chinese patent application No. 201710330762.1, filed on May 11, 2017, the entire disclosure of which is incorporated herein by reference as part of this application.

### TECHNICAL FIELD

Embodiments of the present disclosure relate to a pixel defining layer, a manufacturing method thereof, a display substrate and a display device.

### BACKGROUND

Organic light-emitting diode (OLED) display panel includes an organic material film layer. For example, the organic material film layer can be formed by adopting ink-jet printing technology. When manufacturing the organic material film layer by adopting the ink-jet printing technology, it needs to form a pixel defining layer on a glass substrate firstly, and then spray a solution of organic light-emitting material onto the glass substrate formed with the pixel defining layer, so as to form the organic material film layer. For example, the OLED display panel can be manufactured by forming an anode, a hole injection layer, a hole transport layer, an organic material film layer, an electron transport layer, an electron injection layer, a cathode and the like, sequentially, on a glass substrate.

### SUMMARY

At least one embodiment of the present disclosure provides a pixel defining layer, a manufacturing method thereof, a display substrate and a display device so as to reduce a climbing degree of solution on a side surface of the pixel defining layer during ink-jetting, and hence to mitigate an influence to an uniformity of film formation in a pixel region.

At least one embodiment of the present disclosure provides a manufacturing method of a pixel defining layer, including:

providing a base substrate;

forming a lyophilic layer on the base substrate, the lyophilic layer including a top surface and a side surface;

forming a lyophobic layer at least covering the top surface of the lyophilic layer, and forming a surface covering layer covering at least a portion of the side surface of the lyophilic layer, the portion of the side surface being a portion of the side surface close to the base substrate; and

removing the surface covering layer so that the at least a portion of the side surface close to the base substrate is exposed and a pixel defining layer is formed.

According to the method provided by one or more embodiments of the present disclosure, the lyophilic layer is attractive to a solution dissolved with organic electroluminescence material, and the lyophobic layer is repellent to a solution dissolved with organic electroluminescence material.

According to the method provided by one or more embodiments of the present disclosure, the lyophobic layer and the surface covering layer are integrally formed, and constitute a surface covering lyophobic layer which covers the top surface and the side surface of the lyophilic layer,

forming the lyophilic layer on the base substrate, forming the lyophobic layer at least covering the top surface of the lyophilic layer and forming the surface covering layer covering at least a portion of the side surface of the lyophilic layer include:

forming a lyophilic material layer on the base substrate; and

performing a lyophobic process to an exposed surface layer of the lyophilic material layer to obtain the surface covering lyophobic layer.

According to the method provided by one or more embodiments of the present disclosure, performing the lyophobic process to the exposed surface layer of the lyophilic material layer includes:

forming an reactive coating layer on the exposed surface layer of the lyophilic material layer, and causing the reactive coating layer to react with the lyophilic material layer to obtain the surface covering lyophobic layer.

According to the method provided by one or more embodiments of the present disclosure, the lyophobic layer and the surface covering layer are integrally formed, and constitute a surface covering lyophobic layer which covers the top surface and the side surface of the lyophilic layer,

forming the lyophilic layer on the base substrate, forming the lyophobic layer at least covering the top surface of the lyophilic layer and forming the surface covering layer covering at least a portion of the side surface of the lyophilic layer include:

forming a first lyophilic material layer and a second lyophilic material layer covering a top surface and a side surface of the first lyophilic material layer, sequentially, on the base substrate, and a material of the first lyophilic material layer being different from a material of the second lyophilic material layer; and

forming an reactive coating layer configured to react with the second lyophilic material layer on an exposed surface layer of the second lyophilic material layer, and causing the reactive coating layer to react with the surface layer of the second lyophilic material layer to form the surface covering lyophobic layer,

wherein the first lyophilic material layer and an under layer of the second lyophilic material layer not reacted with the reactive coating layer constitute the lyophilic layer.

According to the method provided by one or more embodiments of the present disclosure, forming the lyophilic layer on the base substrate, forming the lyophobic layer at least covering the top surface of the lyophilic layer and forming the surface covering layer covering at least a portion of the side surface of the lyophilic layer include:

forming a first lyophilic material layer and a second lyophilic material layer covering a top surface of the first lyophilic material layer, sequentially, on the base substrate, and a material of the first lyophilic material layer being different from a material of the second lyophilic material layer;

forming the surface covering layer on a side surface of the first lyophilic material layer; and

forming an reactive coating layer configured to react with the second lyophilic material layer on an exposed surface layer of the second lyophilic material layer, and causing the reactive coating layer to, at least, react with the surface layer of the second lyophilic material layer,

wherein the first lyophilic material layer constitutes the lyophilic layer, and the second lyophilic material layer upon reacting with the reactive coating layer is the lyophobic layer; or, the first lyophilic material layer and an under layer of the second lyophilic material layer not reacted with the reactive coating layer constitute the lyophilic layer, and the surface layer of the second lyophilic material layer upon reacting with the reactive coating layer is the lyophobic layer.

According to the method provided by one or more embodiments of the present disclosure, the second lyophilic material layer is made of silicon dioxide, and the reactive coating layer is made of hydrogen fluoride.

According to the method provided by one or more embodiments of the present disclosure, a thickness of the second lyophilic material layer is 0.1 micron-0.5 micron.

According to the method provided by one or more embodiments of the present disclosure, the first lyophilic material layer is made of polyimide.

According to the method provided by one or more embodiments of the present disclosure, a height of the exposed side surface is at least 0.5 micron.

According to the method provided by one or more embodiments of the present disclosure, forming the lyophilic layer on the base substrate, forming the lyophobic layer at least covering the top surface of the lyophilic layer and forming a surface covering layer covering at least a portion of the side surface of the lyophilic layer include:

forming a lyophilic material layer on the base substrate;

providing the surface covering layer on a portion of a side surface of the lyophilic material layer close to the base substrate to form the surface covering layer covering the portion of the side surface of the lyophilic layer close to the base substrate; and

performing a lyophobic process to an exposed surface layer of the lyophilic material layer to form the lyophobic layer covering the top surface of the lyophilic layer and covering the portion of the side surface of the lyophilic layer far away from the base substrate.

According to the method provided by one or more embodiments of the present disclosure, removing the surface covering layer by adopting a peeling method or an etching method.

According to the method provided by one or more embodiments of the present disclosure, in the pixel defining layer, the lyophobic layer covers the top surface of the lyophilic layer and covers a portion of the side surface of the lyophilic layer far away from the base substrate.

According to the method provided by one or more embodiments of the present disclosure, a side surface of the pixel defining layer includes a lyophobic side surface close to the top surface and a lyophilic side surface far away from the top surface, and a ratio of a height of the lyophilic side surface to a height of the pixel defining layer is 1/3-2/3.

According to the method provided by one or more embodiments of the present disclosure, the ratio of the height of the lyophilic side surface to the height of the pixel defining layer is greater than or equal to 1/2 and smaller than or equal to 2/3.

At least one embodiment of the present disclosure further provides a pixel defining layer manufactured by any of the methods described above.

At least one embodiment of the present disclosure further provides a display substrate, including a base substrate and the above-mentioned pixel defining layer disposed on the base substrate.

At least one embodiment of the present disclosure further provides a display device including the above-mentioned display substrate.

### BRIEF DESCRIPTION OF THE DRAWINGS

Hereinafter, the drawings accompanying embodiments of the present disclosure are simply introduced in order to more clearly explain technical solution(s) of the embodiments of the present disclosure. Obviously, the described drawings below are merely related to some of the embodiments of the present disclosure without constituting any limitation thereto.

FIG. 1A is a partial enlarged view of a pixel defining layer;

FIG. 1B is a flow chart of a manufacturing process of the pixel defining layer illustrated in FIG. 1A;

FIG. 1C is a schematic diagram illustrating a profile of a pixel corresponding to the pixel defining layer illustrated in FIG. 1A;

FIG. 2 is a flow chart of a manufacturing method of a pixel defining layer provided by an embodiment of the present disclosure;

FIG. 3A is a method flow chart illustrating forming a lyophilic material layer on a base substrate and performing a lyophobic process to an exposed surface layer of the lyophilic material layer to obtain a lyophobic layer covering a top surface of a lyophilic layer and to obtain a surface covering layer covering a side surface of the lyophilic layer, as provided by an embodiment of the present disclosure;

FIG. 3B is a schematic diagram (a sectional view of a display substrate) illustrating a structure obtained after forming a lyophilic material layer on a base substrate and forming a surface covering lyophobic layer on a top surface and a side surface of the lyophilic material layer, as provided by an embodiment of the present disclosure;

FIG. 4A is a method flow chart illustrating forming a first lyophilic material layer, a second lyophilic material layer covering a top surface and a side surface of the first lyophilic material layer, and a reactive coating layer on an exposed surface layer of the second lyophilic material layer, on a base substrate, to obtain a lyophilic layer, a lyophobic layer covering a top surface of the lyophilic layer, and a surface covering layer covering a side surface of the lyophilic layer, as provided by an embodiment of the present disclosure;

FIG. 4B is a schematic diagram (a sectional view of a display substrate) illustrating a structure obtained after forming a first lyophilic material layer and a second lyophilic material layer covering a top surface and a side surface of the first lyophilic material layer, on a base substrate, as provided by an embodiment of the present disclosure;

FIG. 4C is a schematic diagram (a sectional view of a display substrate) illustrating a structure obtained after forming a first lyophilic material layer, a second lyophilic material layer covering a top surface and a side surface of the first lyophilic material layer, and a reactive coating layer, on a base substrate, as provided by an embodiment of the present disclosure;

FIG. 5A is a method flow chart illustrating forming a first lyophilic material layer, a second lyophilic material layer covering a top surface of the first lyophilic material layer, a surface covering layer on a side surface of the first lyophilic material layer, and a reactive coating layer, on a base substrate, and causing the reactive coating layer to react with a surface layer of the second lyophilic material layer to obtain a lyophilic layer, a lyophobic layer covering a top surface of the lyophilic layer, and a surface covering layer covering a side surface of the lyophilic layer, as provided by an embodiment of the present disclosure;

FIG. 5B is a schematic diagram (a sectional view of a display substrate) illustrating a structure obtained after forming a first lyophilic material layer on a base substrate, forming a second lyophilic material layer covering a top surface of the first lyophilic material layer, forming a surface covering layer on a side surface of the first lyophilic material layer, and forming a reactive coating layer configured to react with the second lyophilic material layer on an exposed surface layer of the second lyophilic material layer, as provided by an embodiment of the present disclosure;

FIG. 6A is a method flow chart illustrating forming a lyophilic material layer on a base substrate, forming a surface covering layer on a portion of a side surface of the lyophilic material layer, and performing a lyophobic process to an exposed surface layer of the lyophilic material layer to form a lyophilic layer, a lyophobic layer covering a top surface of the lyophilic layer, and a surface covering layer covering a side surface of the lyophilic layer, as provided by an embodiment of the present disclosure;

FIG. 6B is a schematic diagram (a sectional view of a display substrate) illustrating a structure obtained after forming a lyophilic material layer on a base substrate, forming a surface covering layer on a portion of a side surface of the lyophilic material layer far away from a top surface of the lyophilic material layer, and forming a lyophobic material layer on an exposed surface layer of the lyophilic material layer, as provided by an embodiment of the present disclosure;

FIG. 7A is a schematic diagram illustrating a structure obtained after removing the surface covering layer in FIG. 3B by an etching process, as provided by an embodiment of the present disclosure;

FIG. 7B is a schematic diagram illustrating a structure obtained after removing the surface covering layer in FIG. 4B by an etching process, as provided by an embodiment of the present disclosure;

FIG. 7C is a schematic diagram illustrating a structure (the second lyophilic material layer is completely converted into the lyophobic layer) obtained after peeling off the surface covering layer covering the side surface of the lyophilic layer in FIG. 5B, as provided by an embodiment of the present disclosure;

FIG. 7D is a schematic diagram illustrating a structure (the second lyophilic material layer is partly converted into the lyophobic layer) obtained after peeling off the surface covering layer covering the side surface of the lyophilic layer in FIG. 5B, as provided by an embodiment of the present disclosure;

FIG. 7E is a schematic diagram illustrating a structure obtained after peeling off the surface covering layer formed on a lower portion of the side surface of the lyophilic material layer in FIG. 6B, as provided by an embodiment of the present disclosure; and

FIG. 8 is schematic diagram illustrating an arranged height of a solution dissolved with organic electroluminescence material during an ink-jet printing process to a display substrate, as provided by an embodiment of the present disclosure.

### DETAILED DESCRIPTION

In order to make objects, technical details and advantages of the embodiments of the invention apparent, technical solutions according to the embodiments of the present invention will be described clearly and completely as below in conjunction with the accompanying drawings of embodiments of the present invention. It is to be understood that the described embodiments are only a part of but not all of exemplary embodiments of the present invention. Based on the described embodiments of the present invention, various other embodiments can be obtained by those of ordinary skill in the art without creative labor and those embodiments shall fall into the protection scope of the present invention.

Compared to liquid crystal display, organic electroluminescence diode display possesses advantages such as self-illumination, quick response, wide viewing angle, high brightness, vivid colors and small weight and size. Methods of manufacturing film layers in the organic electroluminescence diode can be classified into two types of evaporation process and solution process. The evaporation process is applicable for a film formation of small organic molecular materials, and is advantageous in good uniformity of film formation and relatively developed technologies. The solution process includes methods such as spin coating, ink-jet printing, nozzle-based coating, and screen printing. The ink-jet printing technology is widely applied in the manufacturing process of large-scaled organic electroluminescence diode displays because of its advantages such as higher material utilization and significant superiority in production of large-scaled products. When the ink-jet printing technology is used for manufacturing an organic material film layer, it needs to, first of all, form a pixel defining layer on a base substrate, for example, a glass substrate, and then spray a solution of organic light-emitting material onto the base substrate formed with the pixel defining layer, so as to form an organic material film layer.

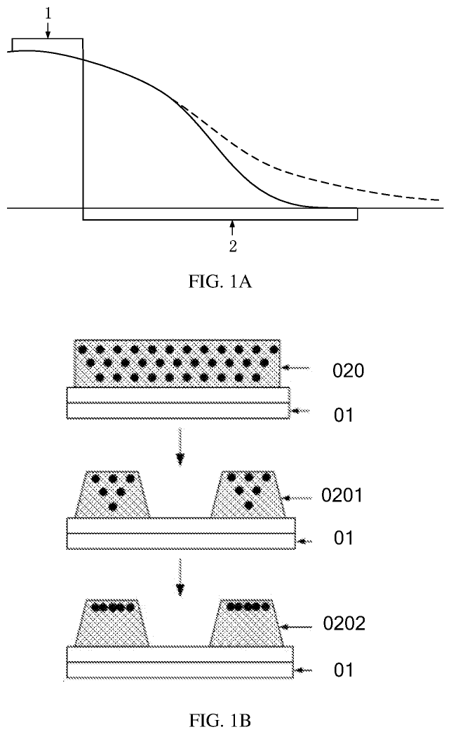

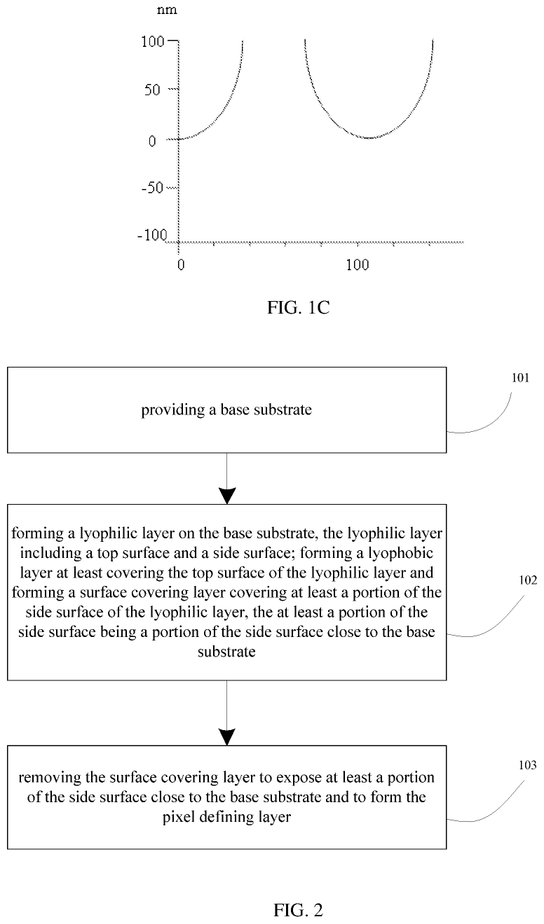

For example, a structure of the pixel defining layer is mainly classified into two types. On one aspect, the pixel defining layer is consisted of a film layer, the pixel defining layer is made of a fluorine-containing material, and represents lyophobic property at its top surface and represents lyophilic property at the remaining portion. A partial enlarged view of the pixel defining layer can be referred to FIG. 1A. As illustrated in FIG. 1A, the numeral “1” indicates a portion of the pixel defining layer representing the lyophobic property, while the numeral “2” indicates a portion of the pixel defining layer representing the lyophilic property. A manufacturing process of the pixel defining layer can be referred to FIG. 1B.

As illustrated in FIG. 1B, forming a pixel defining material layer 020 on a base substrate 01, patterning the pixel defining material layer 020 to form a pattern of pixel defining layer 0201, baking the pattern of pixel defining layer 0201 to obtain a pixel defining layer 0202. The dark spot indicates a fluorine constituent in the fluorine-containing material, and a density of the dark spot indicates a concentration of the fluorine constituent. During the manufacturing process, the fluorine constituent will move upwards to a top surface of the pixel defining layer under the effect of baking, so that the top surface of the pixel defining layer represents lyophobic property while the remaining portion represents lyophilic property. For example, the pixel defining layer can be regarded as consisting of two film layers stacked one on another, in which a lower layer is made of a lyophilic material (inorganic material or other organic material) and an upper layer is made of a fluorine-containing resin material with lyophobic property. During the manufacturing process of this pixel defining layer, baking also allows the fluorine constituent in the fluorine-containing resin material of the upper layer to move upwards to the top surface of the upper layer, so that the top surface represents the lyophobic property while the remaining portion represents the lyophilic property. For example, because the top surface of the pixel defining layer represents the lyophobic property and the remaining portion represents the lyophilic property, that is to say, a side surface of the pixel defining layer is insufficient in lyophobic property, ink may climb on the side surface of the pixel defining layer to a certain degree (as denoted by the dash line in FIG. 1A) during the ink-jet printing process, which results in a film thickness formed in a pixel region corresponding to the pixel defining layer failing to achieve a predetermined value, a poor uniformity inside the pixel, and a U-shaped profile of the pixel (as illustrated by the curved line in FIG. 1C). For example, the dimension in FIG. 1C is a dimension relevant to the pixel.

For example, in conventional technology, the pixel defining layer is made of a fluorine-containing resin material, and the fluorine-containing resin material is subject to a baking process during manufacturing. In such process, the fluorine constituent in the fluorine-containing resin material moves upwards to an upper portion of the pixel defining layer and is formed into a fluorine-containing layer with a certain thickness. This fluorine-containing layer has good lyophobic property, while the remaining portion of the pixel defining layer except the fluorine-containing layer has good lyophilic property.

However, the fluorine constituent merely moves upwards to the upper portion of the pixel defining layer and barely moves to the side surface of the pixel defining layer. During the ink-jet printing process, the fluorine-containing layer with lyophilic property in the pixel defining layer has a repellent action to the solution dissolved with organic light-emitting material, so as to prevent the solution from being sprayed onto an adjacent pixel region. During the ink-jet printing process, the lyophilic portion of the pixel defining layer has an attractive action to the solution dissolved with organic light-emitting material, and the solution would climb on the side surface of the pixel defining layer to a certain degree during ink-jetting, which affects the uniformity of film formation in the pixel region and results in an organic film layer with uneven thickness to be formed in the pixel region.

At least one embodiment of the present application provides a manufacturing method of a pixel defining layer. As illustrated in FIG. 2, the method may include:

Step S101, providing a base substrate;

Step S102, forming a lyophilic layer on the base substrate, the lyophilic layer including a top surface and a side surface; forming a lyophobic layer at least covering the top surface of the lyophilic layer and forming a surface covering layer covering at least a portion of the side surface of the lyophilic layer, the at least a portion of the side surface being a portion of the side surface close to the base substrate;

Step S103, removing the surface covering layer to expose at least a portion of the side surface close to the base substrate and to form the pixel defining layer.

For example, the lyophilic layer is attractive to the solution dissolved with organic electroluminescence material, and the lyophobic layer is repellent to the solution dissolved with organic electroluminescence material.

In the manufacturing method of a pixel defining layer provided by at least one embodiment of the present disclosure, by forming a lyophilic layer on a base substrate, forming a lyophobic layer at least covering a top surface of the lyophilic layer, forming a surface covering layer covering at least a portion of a side surface of the lyophilic layer, and by removing the surface covering layer to expose at least a portion of the side surface of the lyophilic layer close to the base substrate, the pixel defining layer as manufactured includes a lyophobic layer having a top surface and a side surface both repellent to a solution dissolved with organic electroluminescence material, so that the side surface of the pixel defining layer includes a lyophobic side surface with lyophobic property, which reduces the climbing degree of the solution on the side surface of the pixel defining layer during ink-jetting and reduces the affection to the uniformity of film formation in the pixel region.

For example, the top surface is connected with the side surface, and the side surface includes a portion connected with the top surface and a portion far away from the top surface.

For example, in the step S101, the base substrate can be a substrate made of a nonmetallic material with certain robustness and optical transmittance, which is at least one of glass, silicon, quartz, plastic and the like; the base substrate usually is a transparent substrate. Further, for example, the material of the base substrate is glass.

For example, in the step S102, the process of forming a lyophilic layer on the base substrate, forming a lyophobic layer at least covering the top surface of the lyophilic layer and forming a surface covering layer covering at least a portion of the side surface of the lyophilic layer may be achieved by multiple ways. The embodiments of the present disclosure will describe this process with reference to the following four ways, by way of example.

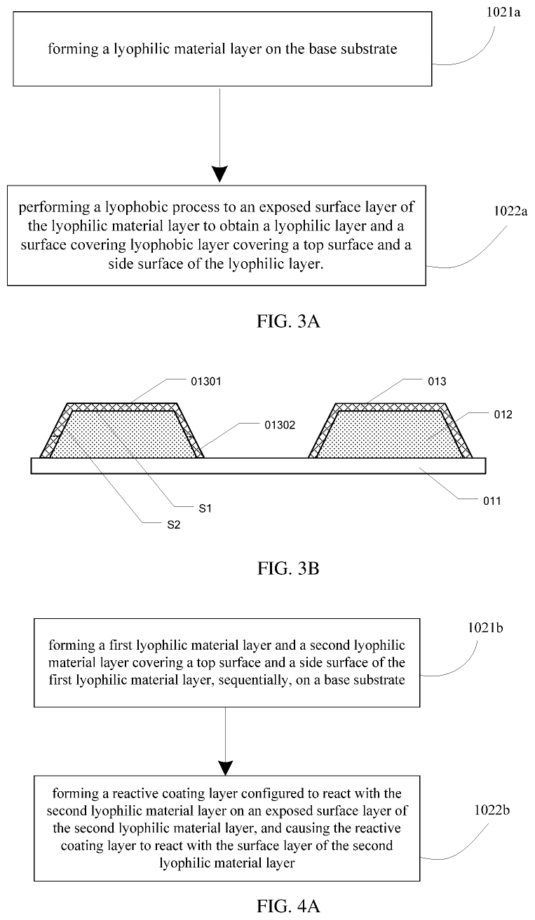

The first way includes: forming a lyophilic material layer on the base substrate and performing a lyophobic process to an exposed surface of the lyophilic material layer to obtain a lyophobic layer at least covering the top surface of the lyophilic layer and a surface covering layer covering a portion of the side surface of the lyophilic layer. As illustrated in FIG. 3A, the process may include:

Step S1021a, forming a lyophilic material layer on the base substrate.

For example, the lyophilic material layer may be made of polyimide (PI), or may also be made of at least one material attractive to the solution dissolved with organic electroluminescence material, such as silicon dioxide and silicon nitride.

For example, when the lyophilic material layer is made of PI, the PI can be coated on the base substrate at a certain thickness to obtain a PI film layer, and then the PI film layer is exposed, developed and baked to obtain a lyophilic material layer with a certain pattern.

For example, when the lyophilic material layer is made of at least one inorganic lyophilic material such as silicon dioxide and silicon nitride, a layer of lyophilic material can be deposited on the base substrate at a certain thickness by using methods such as magnetron sputtering, thermal evaporation and plasma enhanced chemical vapor deposition (PECVD) to obtain a lyophilic material film layer, and then the lyophilic material film layer is processed by a patterning process to obtain a lyophilic material layer with a certain pattern.

Step S1022a, performing a lyophobic process to an exposed surface layer of the lyophilic material layer to obtain a lyophilic layer and a surface covering lyophobic layer covering a top surface and a side surface of the lyophilic layer. The lyophobic layer and the surface covering layer are integrally formed and constitute the surface covering lyophobic layer which covers the top surface and the side surface of the lyophilic layer.

For example, the process of performing a lyophobic process to an exposed surface layer of the lyophilic material layer may include the following.

Forming a reactive coating layer on the exposed surface layer of the lyophilic material layer, and causing the reactive coating layer to react with the lyophilic material layer to obtain the surface covering lyophobic layer; the surface covering lyophobic layer includes a lyophobic layer and a surface covering layer. Or, forming a lyophobic material layer on the exposed surface layer of the lyophilic material layer; the lyophobic material layer is made of a lyophobic material, and the lyophobic material layer as formed is just the surface covering lyophobic layer; the surface covering lyophobic layer includes a lyophobic layer and a surface covering layer. For example, a material of reactive coating layer can be sprayed onto the exposed surface layer of the lyophilic material layer by spraying to form a reactive coating layer with a certain thickness; the reactive coating layer can react with the lyophilic material layer to obtain a layer with lyophobic property. The lyophobic material can be a material repellent to the solution dissolved with organic electroluminescence material such as fluorizated polymethyl methacrylate and polysiloxane.

For example, referring to FIG. 3B which is a schematic diagram illustrating a structure obtained after forming a lyophilic material layer 012 on a base substrate 010 and forming a surface covering lyophobic layer 013 on the base substrate 011 formed with the lyophilic material layer 012, as provided by an embodiment of the present disclosure. For example, the surface covering lyophobic layer 013 covers a top surface and a side surface of the lyophilic material layer 012. For example, the surface covering lyophobic layer 013 includes a lyophobic layer 01301 and a surface covering layer 01302. For example, value ranges of thicknesses of the lyophilic material layer 012 and the surface covering lyophobic layer 013 may be set according to actual demands, without particularly limited in the embodiments of the present disclosure.

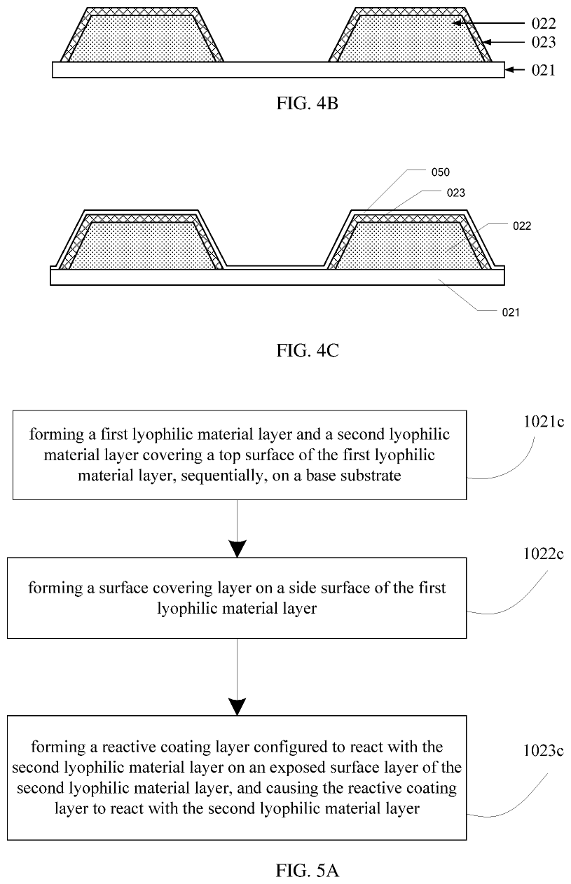

The second way includes: forming a first lyophilic material layer, a second lyophilic material layer covering a top surface and a side surface of the first lyophilic material layer, and a reactive coating layer covering an exposed surface layer of the second lyophilic material layer on a base substrate, and causing the reactive coating layer to react with the surface layer of the second lyophilic material layer to obtain a lyophilic layer, a lyophobic layer at least covering a top surface of the lyophilic layer, and a surface covering layer covering a portion of a side surface of the lyophilic layer. As illustrated in FIG. 4A, such process may include:

Step S1021b, forming a first lyophilic material layer and a second lyophilic material layer covering a top surface and a side surface of the first lyophilic material layer, sequentially, on a base substrate.

For example, the first lyophilic material layer may be made of at least one material of materials attractive to the solution dissolved with organic electroluminescence material such as PI, silicon dioxide and silicon nitride; the second lyophilic material layer may also be made of at least one material of materials attractive to the solution dissolved with organic electroluminescence material such as PI, silicon dioxide and silicon nitride, and the material of the second lyophilic material layer is different from the material of the first lyophilic material layer. For example, a thickness of the second lyophilic material layer may be 0.1 micron-0.5 micron without limited thereto. By way of example, when the first lyophilic material layer is made of PI, the second lyophilic material layer can be made of silicon dioxide.

As for the process of forming a first lyophilic material layer on a base substrate and the process of forming a second lyophilic material layer covering a top surface and a side surface of the first lyophilic material layer on the base substrate formed with the first lyophilic material layer, reference may be made to the process of forming a lyophilic material layer on a base substrate in the step S1021a correspondingly, without repeating herein.

Step S1022b, forming a reactive coating layer configured to react with the second lyophilic material layer on an exposed surface layer of the second lyophilic material layer, and causing the reactive coating layer to react with the surface layer of the second lyophilic material layer.

For example, the first lyophilic material layer and an under layer of the second lyophilic material layer not reacted with the reactive coating layer constitute a lyophilic layer, the surface layer of the second lyophilic material layer upon reacting with the reactive coating layer is a surface coating lyophobic layer which covers a top surface and a side surface of the lyophilic layer. The surface coating lyophobic layer includes a surface covering layer and a lyophobic layer. The lyophobic layer and the surface covering layer, integrally, constitute the surface covering lyophobic layer.

For example, when the second lyophilic material layer is made of silicon dioxide, the reactive coating layer can be made of hydrogen fluoride. An aqueous solution of hydrogen fluoride can be sprayed onto the exposed surface layer of the second lyophilic material layer, by spraying, to form a hydrogen fluoride layer with a certain thickness; the hydrogen fluoride layer can react with the lyophilic material layer made of silicon dioxide to generate a compound of silica and fluorine which has a contact angle of 70° and is repellent to the solution dissolved with organic electroluminescence material; the film layer formed by the compound of silica and fluorine generated by the reaction is just a layer with lyophobic property which includes a lyophobic layer and a surface covering layer; the first lyophilic material layer and the second lyophilic material layer not reacted with the hydrogen fluoride, together, constitute the lyophilic layer.

By way of example, referring to FIG. 4B which is a schematic diagram illustrating a structure obtained after forming a first lyophilic material layer 022 and a second lyophilic material layer 023 covering a top surface and a side surface of the first lyophilic material layer 022, on a base substrate 021, as provided by an embodiment of the present disclosure. For example, value ranges of thicknesses of the first lyophilic material layer 022 and the second lyophilic material layer 023 may be set according to actual demands, without particularly limited in the embodiments of the present disclosure. For example, as illustrated in FIG. 4C, in practical application, a reactive coating layer 050 may be further disposed on the exposed surface layer of the second lyophilic material layer. For example, the reactive coating layer has a relatively small thickness. For example, the reactive coating layer may be reacted with the second lyophilic material layer to obtain a lyophobic layer or a surface covering lyophobic layer.

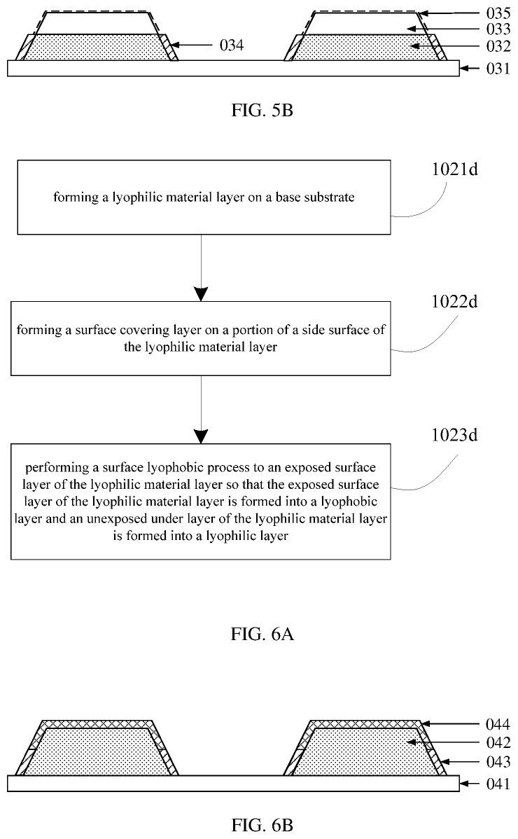

The third way includes: forming a first lyophilic material layer, a second lyophilic material layer covering a top surface of the first lyophilic material layer, a surface covering layer covering a side surface of the first lyophilic material layer, and forming a reactive coating layer, on a base substrate; and causing the reactive coating layer to react with a surface layer of the second lyophilic material layer to obtain a lyophilic layer, a lyophobic layer covering a top surface of the lyophilic layer, and a surface covering layer covering a side surface of the lyophilic layer. As illustrated in FIG. 5A, the process may include:

Step S1021c, forming a first lyophilic material layer and a second lyophilic material layer covering a top surface of the first lyophilic material layer, sequentially, on a base substrate.

For example, the first lyophilic material layer may be made of at least one material of materials attractive to a solution dissolved with organic electroluminescence material, such as PI, silicon dioxide and silicon nitride; the second lyophilic material layer may also be made of at least one material of materials attractive to the solution dissolved with organic electroluminescence material, such as PI, silicon dioxide and silicon nitride, and the material of the second lyophilic material layer is different from the material of the first lyophilic material layer.

As for the process of forming a first lyophilic material layer on a base substrate and the process of forming a second lyophilic material layer covering a top surface of the first lyophilic material layer on the base substrate formed with the first lyophilic material layer, reference may be made to the process of forming a lyophilic material layer on a base substrate in the step S1021a correspondingly, without repeating herein.

Step S1022c, forming a surface covering layer on a side surface of the first lyophilic material layer.

The surface covering layer as formed can shield the side surface of the first lyophilic material layer so that the side surface of the first lyophilic material layer would not be affected by a process performed to the second lyophilic material layer covering the top surface of the first lyophilic material layer. For example, a material of the surface covering layer may be determined by a processing method performed to the second lyophilic material layer, as long as the processing method would not affect the surface covering layer. For example, when the process performed to the second lyophilic material layer is to form a reactive coating layer on the second lyophilic material layer and cause the reactive coating layer to react with the second lyophilic material layer, the surface covering layer is made of a material which does not react with the reactive coating layer.

For example, when the material of the surface covering layer is an inorganic material, a layer of inorganic material having a certain thickness may be deposited on the base substrate formed with the second lyophilic material layer by using methods such as magnetron sputtering, thermal evaporation and PECVD to obtain a surface covering film layer, and then the surface covering film layer is processed by a patterning process to obtain a surface covering layer which is provided with a certain pattern and covers the side surface of the first lyophilic material layer, without limited thereto. For example, the surface covering layer can only cover the side surface of the first lyophilic material layer, without limited thereto. For example, the surface covering layer may cover any position except the second lyophilic material layer; for example, the position includes a position between the side surface of the first lyophilic material layer and an adjacent first lyophilic material layer. For example, when the material of the surface covering layer is an organic material, a layer of organic material having a certain thickness may be coated on the base substrate formed with the second lyophilic material layer to obtain a surface covering film layer, and the surface covering film layer may be subjected to processes such as exposing, developing and baking, to obtain a surface covering layer which is provided with a certain pattern and covers the side surface of the first lyophilic material layer.

Step S1023c, forming a reactive coating layer configured to react with the second lyophilic material layer on an exposed surface layer of the second lyophilic material layer, and causing the reactive coating layer to react with the second lyophilic material layer.

For example, the first lyophilic material layer and an under layer of the second lyophilic material layer not reacted with the first lyophilic material layer constitute a lyophilic layer, and the surface layer of the second lyophilic material layer upon reacting with the first lyophilic material layer is a lyophobic layer. For example, the lyophobic layer covers a top surface of the lyophilic layer and covers a portion of a side surface of the lyophilic layer close to the top surface of the lyophilic layer.

For example, as for the process of forming a reactive coating layer configured to react with the second lyophilic material layer on an exposed surface layer of the second lyophilic material layer and causing the reactive coating layer to react with the surface layer of the second lyophilic material layer, reference may be made to the process of implementing the step S1022b correspondingly, without repeating herein.

For example, referring to FIG. 5B which is a schematic diagram illustrating a structure obtained after forming a first lyophilic material layer 032, a second lyophilic material layer 033 covering a top surface of the first lyophilic material layer 032, a surface covering layer 034 on a side surface of the first lyophilic material layer 032, and a reactive coating layer 035 (the coating layer indicated by the dash line) configured to react with the second lyophilic material layer 033 on an exposed surface layer of the second lyophilic material layer 033, on a base substrate 031, as provided by an embodiment of the present disclosure. For example, value ranges of thicknesses of the first lyophilic material layer 032, the second lyophilic material layer 033, the surface covering layer 034 and the reactive coating layer 035 all may be set according to actual demands, without particularly limited in the embodiments of the present disclosure. For example, the second lyophilic material layer 033 only covers the top surface of the first lyophilic material layer 032. For example, the surface covering layer 034 is formed on the entire side surface of the first lyophilic material layer 032.

The fourth way includes: forming a lyophilic material layer on a base substrate, forming a surface covering layer on a lower portion of a side surface of the lyophilic material layer, and performing a lyophobic process to an exposed surface layer of the lyophilic material layer to obtain a lyophilic layer, a lyophobic layer at least covering a top surface of the lyophilic layer, and a surface covering layer covering a portion of a side surface of the lyophilic layer. As illustrated in FIG. 6A, the process may include:

Step S1021d, forming a lyophilic material layer on a base substrate.

For example, the lyophilic material layer may be made of at least one of materials attractive to the solution dissolved with organic electroluminescence material, such as PI, silicon dioxide and silicon nitride.

As for the process of forming a lyophilic material layer on a base substrate, reference may be made to the process of forming a lyophilic material layer on a base substrate in the step S1021a correspondingly, without repeating herein.

Step S1022d, forming a surface covering layer on a portion of a side surface of the lyophilic material layer. For example, the portion of the side surface is a portion of the side surface far away from the top surface of the lyophilic material layer.

For example, the portion of the side surface of the lyophilic material layer may be a portion of the lyophilic material layer having a certain height with reference to the base substrate, for example, a height of 0.5 micron. As for the process of forming a surface covering layer on a portion of a side surface of the lyophilic material layer, reference may be made to the process of forming a surface covering layer on a side surface of the first lyophilic material layer in the step S1022c correspondingly, without repeating herein.

Step S1023d, performing a surface lyophobic process to an exposed surface layer of the lyophilic material layer so that the exposed surface layer of the lyophilic material layer is formed into a lyophobic layer and an unexposed under layer of the lyophilic material layer is formed into a lyophilic layer.

Upon performing the surface lyophobic process to the exposed surface layer of the lyophilic material layer, a lyophilic layer and a lyophobic layer at least covering a top surface of the lyophilic layer can be formed on the base substrate. For example, the lyophobic layer may cover the top surface of the lyophilic layer and cover at least part of a side surface of the lyophilic layer connected with the top surface. For example, the process of performing a surface lyophobic process to the exposed surface layer of the lyophilic material layer may include: forming a reactive coating layer on an exposed surface layer of the lyophilic material layer and causing the reactive coating layer to react with the lyophilic material layer to obtain a lyophobic layer. For example, after the lyophobic process, a surface covering lyophobic layer can be formed to cover the top surface and the entire side surface of the lyophilic layer, and the surface covering lyophobic layer may include a lyophobic layer and a surface covering layer. Or, forming a lyophobic material layer made of a lyophobic material on the exposed surface layer of the lyophilic material layer; the lyophobic material layer as formed is just the surface covering lyophobic layer, and the surface covering lyophobic layer may include a lyophobic layer and a surface covering layer.

For example, referring to FIG. 6B which is a schematic diagram illustrating a structure obtained by forming a lyophilic material layer 042 on a base substrate 041, forming a surface covering layer 043 on a portion of a side surface of the lyophilic material layer 042 far away from a top surface of the lyophilic material layer 042, and forming a lyophobic material layer 044 on an exposed surface layer of the lyophilic material layer 042, as provided by an embodiment of the present disclosure. For example, value ranges of thicknesses of the lyophilic material layer 042, the surface covering layer 043 and the lyophobic material layer 044 can be set according to actual demands, without particularly limited in the embodiments of the present disclosure.

For example, in the step S103, the process of removing the surface covering layer to expose at least a portion of the side surface of the lyophilic layer far away from the top surface of the lyophilic layer may include: removing the surface covering layer by a peeling method, or removing the surface covering layer by an etching process. For example, the side surface that is exposed by removing the surface covering layer may be 0.5 micron. For example, the etching process may be a dry etching process.

The two solutions for removing may be selected according to actual demands. For example, when the lyophobic process is to cause the side surface of the lyophilic layer to react with the reactive coating layer, or when the lyophobic process is to cause the second lyophilic material layer covering the top surface and the side surface of the first lyophilic material layer to react with the reactive coating layer, the etching process can be selected to remove the surface covering layer which covers the side surface of the lyophilic layer, in case that the surface covering layer is formed on the side surface of the first lyophilic material layer and then the reactive coating layer is caused to react with the surface layer of the second lyophilic material layer, or, in case that the surface covering layer is formed on a portion of the side surface of the lyophilic material layer far away from the top surface and then the lyophobic process is performed to the exposed surface layer of the lyophilic material layer, the peeling method may be selected to remove the surface covering layer which covers the side surface of the lyophilic layer.

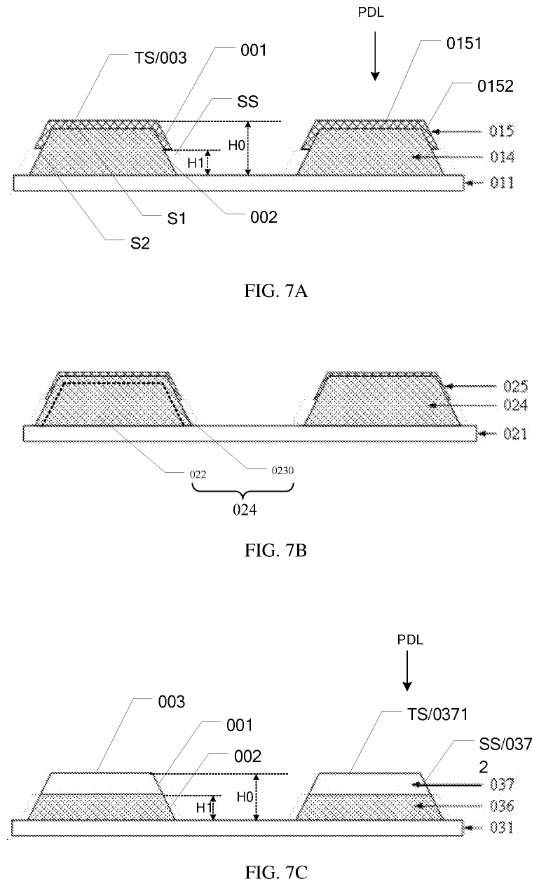

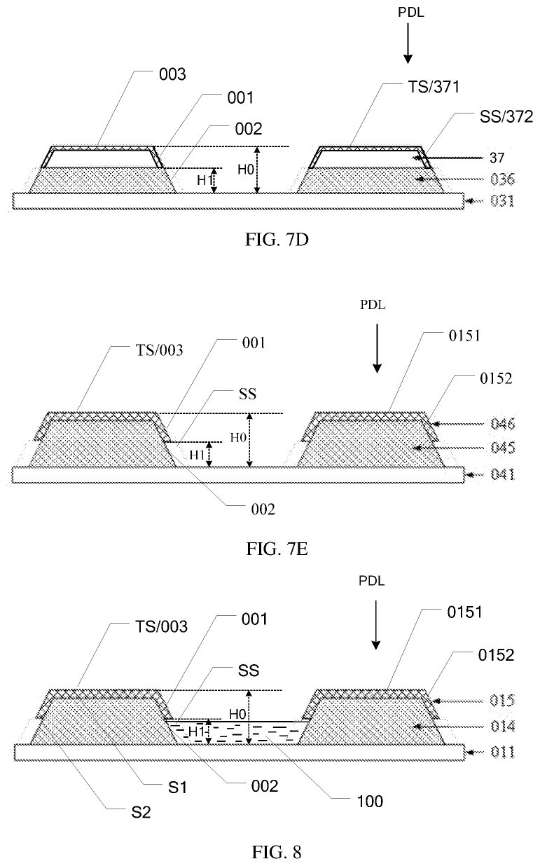

For example, referring to FIG. 7A, FIG. 7A is a schematic diagram illustrating a structure obtained after removing the surface covering layer in FIG. 3B by an etching process. For example, a lyophobic material layer 013 is formed on a surface layer of the lyophilic material layer 012 in FIG. 3B, and the surface covering layer is a portion of the lyophobic material layer 013 within a certain height, for example, within a height of 0.5 micron, on the side surface of the lyophilic material layer 012. After the etching process, the lyophilic material layer 012 is the lyophilic layer 014 in the pixel defining layer as illustrated in FIG. 7A, and the remaining lyophobic material layer 013 upon etching is the lyophobic layer 015 in the pixel defining layer as illustrated in FIG. 7A.

For example, as illustrated in FIG. 7A, the lyophilic layer 014 includes a top surface S1 and a side surface S2.

For example, as illustrated in FIG. 7A, the pixel defining layer PDL includes a top surface TS and a side surface SS; the side surface SS of the pixel defining layer PDL includes a lyophobic side surface 001 and a lyophilic side surface 002 which are adjacent to each other. For example, the lyophobic side surface 001 is farther from the base substrate 011 than the lyophilic side surface 002. For example, the lyophobic side surface 001 is closer to the top surface TS than the lyophilic side surface 002. The top surface TS of the pixel defining layer PDL is a lyophobic surface 003.

For example, a ratio of a height H1 of the lyophilic side surface 002 in a direction perpendicular to the base substrate 011 to a height H0 of the pixel defining layer PDL in the direction perpendicular to the base substrate 011 is in the range smaller than or equal to 2/3. For example, the ratio of the height H1 of the lyophilic side surface 002 in the direction perpendicular to the base substrate 011 to the height H0 of the pixel defining layer PDL in the direction perpendicular to the base substrate 011 is in the range of 1/3-2/3; further, for example, the ratio is greater than or equal to 1/2, and is smaller than or equal to 2/3.

For example, as illustrated in FIG. 7A, the lyophobic layer 015 includes a top lyophobic layer 0151 located at a top surface of the lyophilic layer 014 and a side lyophobic layer 0152 located at a portion of the side surface of the lyophilic layer 014 close to the top surface.

For example, referring to FIG. 7B, FIG. 7B is a schematic diagram illustrating a structure obtained after removing the surface covering layer in FIG. 4B by an etching process. For example, in FIG. 4B, a second lyophilic material layer 023 is formed on the top surface and the side surface of the first lyophilic material layer 022, and a portion of the second lyophilic material layer 023 reacts with the reactive coating layer, the surface layer of the second lyophilic material layer 023 after the reaction is a lyophobic layer, and a film layer portion of the lyophobic layer within a certain height, for example, within a height of 0.5 micron, with respect to the side surface of the lyophilic material layer 012 is a surface covering layer; upon the etching process, the first lyophilic material layer 022 and an under layer 0230 of the second lyophilic material layer 023 not reacted with the reactive coating layer constitute the lyophilic layer 024 in the pixel defining layer as illustrated in FIG. 7B, and the remaining lyophobic layer upon etching is the lyophobic layer 025 in the pixel defining layer as illustrated in FIG. 7B.

For example, referring to FIG. 7C, FIG. 7C is a schematic diagram illustrating a structure obtained after peeling off the surface covering layer 034 covering the side surface of the lyophilic layer in FIG. 5B. For example, the top surface of the first lyophilic material layer 032 in FIG. 5B is formed into the second lyophilic material layer 033, the entire second lyophilic material layer 033 reacts with the reactive coating layer, and the second lyophilic material layer 033 upon reaction represents lyophobic property; upon peeling off the surface covering layer, the first lyophilic material layer 032 is the lyophilic layer 036 in the pixel defining layer as illustrated in FIG. 7C, and the second lyophilic material layer 033 upon reaction is the lyophobic layer 037 in the pixel defining layer as illustrated in FIG. 7C.

For example, as illustrated in FIG. 7C, the pixel defining layer PDL includes a top surface TS and a side surface SS; the side surface SS of the pixel defining layer PDL includes a lyophobic side surface 001 and a lyophilic side surface 002 which are adjacent to each other. For example, the lyophobic side surface 001 is farther from the base substrate 011 than the lyophilic side surface 002. For example, the lyophobic side surface 001 is closer to the top surface TS than the lyophilic side surface 002. The top surface TS of the pixel defining layer PDL is a lyophobic surface 003. For example, a ratio of a height H1 of the lyophilic side surface 002 in a direction perpendicular to the base substrate 011 to a height H0 of the pixel defining layer PDL in the direction perpendicular to the base substrate 011 is in a range smaller than or equal to 2/3. For example, the ratio of the height H1 of the lyophilic side surface 002 in the direction perpendicular to the base substrate 011 to the height H0 of the pixel defining layer PDL in the direction perpendicular to the base substrate 011 is in the range of 1/3-2/3; further, for example, the ratio is greater than or equal to 1/2, and is smaller than or equal to 2/3.

FIG. 7D illustrates a schematic diagram of a pixel defining layer manufactured by the method provided by an embodiment of the present disclosure. Compared to FIG. 7C, in FIG. 7D, only the surface layer of the second lyophilic material layer reacts with the reactive coating layer to form a lyophobic layer 37. For example, as illustrated in FIG. 7D, the lyophobic layer 37 includes a top lyophobic layer 371 and a side lyophobic layer 372. As for the top surface TS, the side surface SS, the lyophobic side surface 001, the lyophilic side surface 002, and the height configuration of the lyophilic side surface 002 of the pixel defining layer, reference may be made to the description of FIG. 7A, without repeating herein.

For example, referring to FIG. 7E, FIG. 7E is a schematic diagram illustrating a structure obtained after peeling off the surface covering layer 043 formed on a portion of the side surface of the lyophilic material layer 042 far away from the top surface in FIG. 6B. For example, the exposed surface layer of the lyophilic material layer 042 in FIG. 6B is formed into a lyophobic material layer 044; upon peeling off the surface covering layer 043, the lyophilic material layer 042 is the lyophilic layer 045 in the pixel defining layer as illustrated in FIG. 7E, and the lyophobic material layer 044 formed by the exposed surface layer of the lyophilic material layer 042 is the lyophobic layer 046 in the pixel defining layer as illustrated in FIG. 7E.

As for the top surface TS, the side surface SS, the lyophobic side surface 001, the lyophilic side surface 002, and the height configuration of the lyophilic side surface 002 of the pixel defining layer in FIG. 7E, reference may be made to the description of FIG. 7A without repeating herein.

For example, as illustrated in FIG. 8, in order to reduce ink climbing, during the ink-jet printing process, a height of a solution 100 dissolved with organic electroluminescence material in the direction perpendicular to the base substrate 011 is smaller than or equal to a height of the lyophilic side surface 002 in the direction perpendicular to the base substrate 011 without limited thereto. For example, the height configuration of the solution 100 dissolved with organic electroluminescence material as illustrated in FIG. 8 is also applicable for the pixel defining layer provided by other embodiments of the present disclosure.

In the manufacturing method of a pixel defining layer provided by at least one embodiment of the present disclosure, by forming a lyophilic layer, a lyophobic layer at least covering a top surface of the lyophilic layer, and a surface covering layer covering at least part of a side surface of the lyophilic layer, on a base substrate, and by removing the surface covering layer to expose the side surface covered by the surface covering layer, the pixel defining layer as manufactured includes a lyophobic layer having a top surface and a side surface both repellent to the solution dissolved with organic electroluminescence material, which reduces a climbing extent of the solution on the side surface during ink-jetting, reduces the influence to the uniformity of film formation in the pixel region and the pixel profile, and allows for controlling a height of ink-jetting opening according to requirements and demands; at the same time, because a climbing height of the solution on the side surface of the pixel defining layer is reduced, a film layer with a predetermined thickness can be printed by using an ink amount calculated within an error range, so as to improve the printing effect.

It should be explained that, a sequential order of the steps in the manufacturing method of a pixel defining layer as provided by the embodiments of the present disclosure can be adjusted appropriately, and corresponding addition(s) or deletion(s) can be made to these steps according to conditions. In the embodiments of the present disclosure, patterning or a patterning process may only include a photolithographic process, or may include both of the photolithographic process and etching step(s), or may include printing, ink-jetting or other processes for forming a predetermined pattern. The photolithographic process includes technical processes such as film forming, exposing, and developing, and forms a pattern by using photoresist, mask, exposure machine and the like. The patterning process can be selected according to the structure(s) formed in the embodiments of the present disclosure. At least one embodiment of the present disclosure provides a pixel defining layer, and a structural diagram of the pixel defining layer can be referred to FIGS. 7A-7E. The pixel defining layer is manufactured by the manufacturing method of a pixel defining layer provided by any of the embodiments of the present disclosure.

For example, in the embodiments of the present disclosure, a top surface of an element/layer refers to a surface of the element/layer farthest from the base substrate. For example, a side surface of an element/layer refers to a surface between a top surface of the element/layer and a lower surface of the element/layer close to the base substrate.

For example, at least one embodiment of the present disclosure provides a pixel defining layer including a lyophilic layer, a lyophobic layer at least covering a top surface of the lyophilic layer, and a surface covering layer covering at least part of a side surface of the lyophilic layer, on a base substrate. By removing the surface covering layer, the side surface of the lyophilic layer covered by the surface covering layer is exposed, so that the pixel defining layer includes a lyophobic layer and the lyophobic layer has a top surface and a side surface both repellent to a solution dissolved with organic electroluminescence material, which reduces the climbing extent of the solution on this side surface during ink-jetting, and reduces the influence to the uniformity of film formation in the pixel region.

The embodiments of the present disclosure provide a display substrate. The display substrate may include a base substrate and a pixel defining layer disposed on the base substrate. The pixel defining layer is any of the pixel defining layers illustrated in FIGS. 7A-7E.

In practical application, the display substrate may further include, at least, an anode disposed between the base substrate and the pixel defining layer, and a cathode disposed on the pixel defining layer. For example, the display substrate is configured to constitute an OLED display panel, and the OLED display panel may include the display substrate provided by the embodiments of the present disclosure and a covering plate disposed above the cathode of the display substrate.

The embodiments of the present disclosure further provide a display device, which can include the above-mentioned OLED display panel. The display device may be any product or component with display function such as a liquid crystal display (LCD) panel, an electronic paper, a mobile phone, a watch, a tablet computer, a television, a displayer, a notebook computer, a digital photo frame, and a navigator.

In case of no conflict, the embodiments of the present disclosure and features(s) in the embodiments may be combined with each other.

The above are merely specific implementations of the present disclosure without limiting the protection scope of the present disclosure thereto. Within the technical scope revealed in the present disclosure, modification(s) or substitution(s) may be easily conceivable for those skilled who are familiar with the present technical field, and these modification(s) and substitution(s) all should be contained in the protection scope of the present disclosure. Therefore the protection scope of the present disclosure should be based on the protection scope of the appended claims.

1. A manufacturing method of a pixel defining layer, comprising:
providing a base substrate;
forming a lyophilic layer on the base substrate, the lyophilic layer comprising a top surface and a side surface;
forming a lyophobic layer at least covering the top surface of the lyophilic layer, and forming a surface covering layer covering at least a portion of the side surface of the lyophilic layer, the portion of the side surface being a portion of the side surface close to the base substrate; and
removing the surface covering layer so that the at least a portion of the side surface close to the base substrate is exposed and a pixel defining layer is formed.

2. The method according to claim 1, wherein the lyophilic layer is attractive to a solution dissolved with organic electroluminescence material, and the lyophobic layer is repellent to a solution dissolved with organic electroluminescence material.

3. The method according to claim 1, wherein the lyophobic layer and the surface covering layer are integrally formed, and constitute a surface covering lyophobic layer which covers the top surface and the side surface of the lyophilic layer,
forming the lyophilic layer on the base substrate, forming the lyophobic layer at least covering the top surface of the lyophilic layer and forming the surface covering layer covering at least a portion of the side surface of the lyophilic layer comprise:
forming a lyophilic material layer on the base substrate; and
performing a lyophobic process to an exposed surface layer of the lyophilic material layer to obtain the surface covering lyophobic layer.

4. The method according to claim 3, wherein performing the lyophobic process to an exposed surface layer of the lyophilic material layer comprises:
forming an reactive coating layer on the exposed surface layer of the lyophilic material layer, and causing the reactive coating layer to react with the lyophilic material layer to obtain the surface covering lyophobic layer.

5. The method according to claim 1, wherein the lyophobic layer and the surface covering layer are integrally formed, and constitute a surface covering lyophobic layer which covers the top surface and the side surface of the lyophilic layer,
forming the lyophilic layer on the base substrate, forming the lyophobic layer at least covering the top surface of the lyophilic layer and forming the surface covering layer covering at least a portion of the side surface of the lyophilic layer comprise:
forming a first lyophilic material layer and a second lyophilic material layer covering a top surface and a side surface of the first lyophilic material layer, sequentially, on the base substrate, and a material of the first lyophilic material layer being different from a material of the second lyophilic material layer; and
forming an reactive coating layer configured to react with the second lyophilic material layer on an exposed surface layer of the second lyophilic material layer, and causing the reactive coating layer to react with the surface layer of the second lyophilic material layer to form the surface covering lyophobic layer,
wherein the first lyophilic material layer and an under layer of the second lyophilic material layer not reacted with the reactive coating layer constitute the lyophilic layer.

6. The method according to claim 1, wherein forming the lyophilic layer on the base substrate, forming the lyophobic layer at least covering the top surface of the lyophilic layer and forming the surface covering layer covering at least a portion of the side surface of the lyophilic layer comprise:
forming a first lyophilic material layer and a second lyophilic material layer covering a top surface of the first lyophilic material layer, sequentially, on the base substrate, and a material of the first lyophilic material layer being different from a material of the second lyophilic material layer;
forming the surface covering layer on a side surface of the first lyophilic material layer; and
forming an reactive coating layer configured to react with the second lyophilic material layer on an exposed surface layer of the second lyophilic material layer, and causing the reactive coating layer to, at least, react with the surface layer of the second lyophilic material layer,
wherein the first lyophilic material layer constitutes the lyophilic layer, and the second lyophilic material layer upon reacting with the reactive coating layer is the lyophobic layer; or, the first lyophilic material layer and an under layer of the second lyophilic material layer not reacted with the reactive coating layer constitute the lyophilic layer, and the surface layer of the second lyophilic material layer upon reacting with the reactive coating layer is the lyophobic layer.

7. The method according to claim 5, wherein the second lyophilic material layer is made of silicon dioxide, and the reactive coating layer is made of hydrogen fluoride.

8. The method according to claim 7, wherein a thickness of the second lyophilic material layer is 0.1 micron-0.5 micron.

9. The method according to claim 7, wherein the first lyophilic material layer is made of polyimide.

10. The method according to claim 1, wherein a height of the exposed side surface is at least 0.5 micron.

11. The method according to claim 1, wherein forming the lyophilic layer on the base substrate, forming the lyophobic layer at least covering the top surface of the lyophilic layer and forming the surface covering layer covering at least a portion of the side surface of the lyophilic layer comprise:
forming a lyophilic material layer on the base substrate;
providing the surface covering layer on a portion of a side surface of the lyophilic material layer close to the base substrate to form the surface covering layer covering the portion of the side surface of the lyophilic layer close to the base substrate; and
performing a lyophobic process to an exposed surface layer of the lyophilic material layer to form the lyophobic layer covering the top surface of the lyophilic layer and covering the portion of the side surface of the lyophilic layer far away from the base substrate.

12. The method according to claim 1, wherein removing the surface covering layer by adopting a peeling method or an etching method.

13. The method according to claim 1, wherein in the pixel defining layer, the lyophobic layer covers the top surface of the lyophilic layer and covers a portion of the side surface of the lyophilic layer far away from the base substrate.

14. The method according to claim 1, wherein a side surface of the pixel defining layer comprises a lyophobic side surface close to the top surface and a lyophilic side surface far away from the top surface, and a ratio of a height of the lyophilic side surface to a height of the pixel defining layer is 1/3-2/3.

15. The method according to claim 14, wherein the ratio of the height of the lyophilic side surface to the height of the pixel defining layer is greater than or equal to 1/2 and smaller than or equal to 2/3.

16. A pixel defining layer manufactured by the method according to claim 1.

17. A display substrate, comprising a base substrate and a pixel defining layer on the base substrate, the pixel defining layer being the pixel defining layer according to claim 16.

18. A display device, comprising the display substrate according to claim 17.

19. The display substrate according to claim 17, wherein in the pixel defining layer, the lyophobic layer covers the top surface of the lyophilic layer and covers a portion of the side surface of the lyophilic layer far away from the base substrate.

20. The display substrate according to claim 17, wherein a side surface of the pixel defining layer comprises a lyophobic side surface close to the top surface and a lyophilic side surface far away from the top surface, and a ratio of a height of the lyophilic side surface to a height of the pixel defining layer is 1/3-2/3.
